(19) United States
(12) Patent Application Publication
(10) Pub. No.: US 2014/0111069 A1
(43) Pub. Date: Apr. 24, 2014

(54) HOUSING STRUCTURE FOR SOLID-STATE DRIVE

(71) Applicants: Wei-Hau CHEN, New Taipei City (TW); Chen-Fong LIN, New Taipei City (TW)

(72) Inventors: Wei-Hau CHEN, New Taipei City (TW); Chen-Fong LIN, New Taipei City (TW)

(73) Assignee: CompTake Technology Inc.

(21) Appl. No.: 13/656,744

(22) Filed: Oct. 22, 2012

(51) Int. Cl. H05K 7/10; H05K 5/03

(52) U.S. Cl. 312/223.2

(57) ABSTRACT

A housing structure for enclosing a solid-state drive (SSD) is disclosed. The housing structure includes a housing and a height adjustment plate. The housing is used for receiving the SSD and has a plurality of engagement recesses on a surface thereof. The height adjustment plate includes a plate body having a predetermined height and a plurality of hooks formed on the plate body. The hooks correspond to the engagement recesses in position and the height adjustment plate is fastened to the housing by engaging the hooks with the engagement recesses for adjusting an overall height of the SSD.

### BACKGROUND OF THE INVENTION

1. Technical Field

The invention relates to solid-state drives (SSDs), particularly to a housing structure which allows an overall height of an SSD to be adjusted.

2. Related Art

A solid-state drive (SSD) is a data storage device that uses integrated circuit assemblies as memory to store data persistently. SSDs do not employ any moving mechanical components, which distinguishes them from traditional magnetic disks such as hard disk drives (HDDs) or floppy disks, which are electromechanical devices containing spinning disks and movable read/write heads. Compared with electromechanical disks, SSDs are typically less susceptible to physical shock, are silent, and have lower access time and latency. Thus, SSDs are progressively popular in the market and usually replace traditional hard drives in portable computers.

Currently, most SSDs use form factors compatible with traditional hard disk drives such as 1.8 inch, 2.5 inch and 3.5 inch form factors. As a result, when assembling an SSD, a plurality of housing modules with different heights (thickness) are required to form different form factors. This will cause higher costs and more complex management of manufacturing process.

### SUMMARY OF THE INVENTION

An object of the invention is to provide a housing structure for a solid-state drive which allows an overall height of the SSD to be adjustable.

Another object of the invention is to provide a housing structure for a solid-state drive which can reduce manufacturing costs and simplify manufacturing process.

To achieve the above objects, the housing structure of the invention includes a housing and a height adjustment plate. The housing is used for receiving the SSD and has a plurality of engagement recesses on a surface thereof. The height adjustment plate includes a plate body having a predetermined height and a plurality of hooks formed on the plate body. The hooks correspond to the engagement recesses in position and the height adjustment plate is fastened to the housing by engaging the hooks with the engagement recesses for adjusting an overall height of the SSD.

In comparison with the prior art, the height of the height adjustment plate can be varied depending upon the actual requirements, so that the invention can be applied to housings of the SSDs with different form factors.

### BRIEF DESCRIPTION OF THE DRAWINGS

FIG. 1 is a schematic view of the invention;

FIG. 2 is an exploded view of the invention;

FIG. 3 is a cross-sectional view of the invention;

FIG. 4 is another cross-sectional view of the invention; and

FIG. 5 is an exploded view of the housing and an SSD.

### DETAILED DESCRIPTION OF THE INVENTION

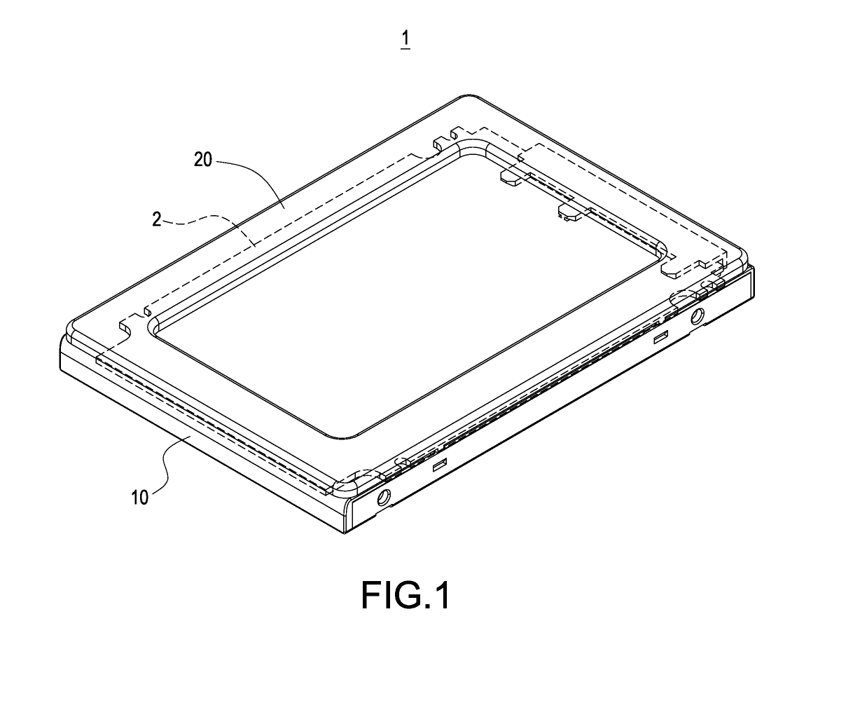

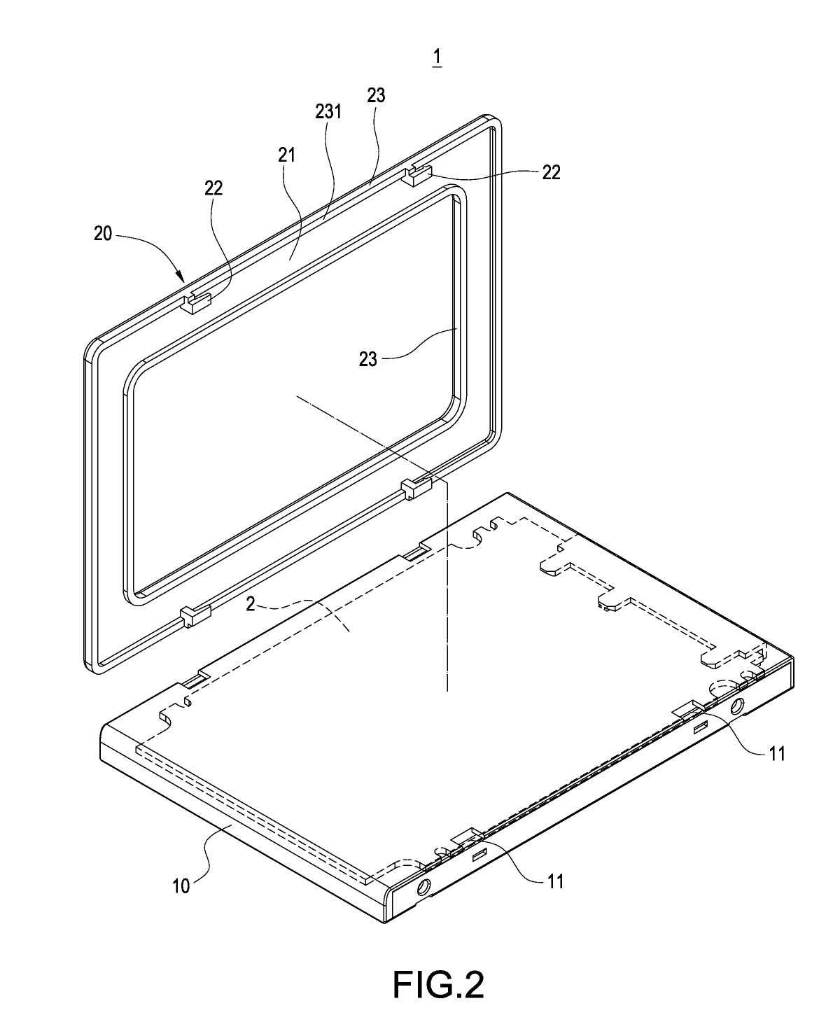

Please refer to FIGS. 1 and 2. The housing structure 1 of the invention includes a housing 10 and a height adjustment plate 20 fastened onto the housing 10.

The housing 10 is used for receiving a solid-state drive (SSD) 2 and is formed with a plurality of engagement recesses 11 on a surface thereof. In an embodiment of the invention, the engagement recesses 11 are located on an edge of the housing 10.

The height adjustment plate 20 includes a plate body 21 having a predetermined height and a plurality of hooks 22 formed on the plate body 21. The hooks 22 correspond to the engagement recesses 11 in position. Preferably, the height adjustment plate 20 corresponds to the housing 10 in shape. In the embodiment, the housing 10 is a cuboid and the plate body 21 is a rectangular frame plate. Besides, the hooks 22 is arranged on the edge of plate body 21, which faces the housing 10, for correspondingly engaging with the engagement recesses 11.

In the embodiment, the plate body 21 has at least one enclosure rib 23. The enclosure rib 23 encloses an inner edge and/or outer edge of the plate body 21, which faces the housing 10. And the enclosure rib 23 has a touch surface 231 which is in contact with the housing 10. Further, the hooks 22 protrude from the touch surface 231 and extend parallelly toward the enclosure rib 23.

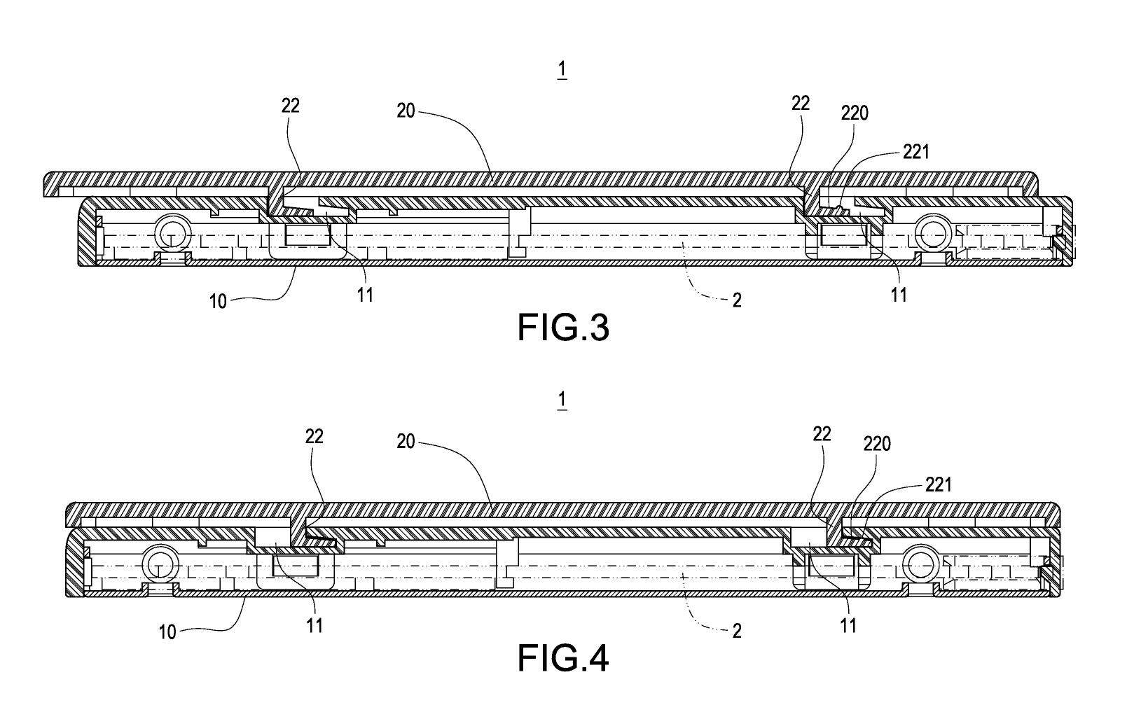

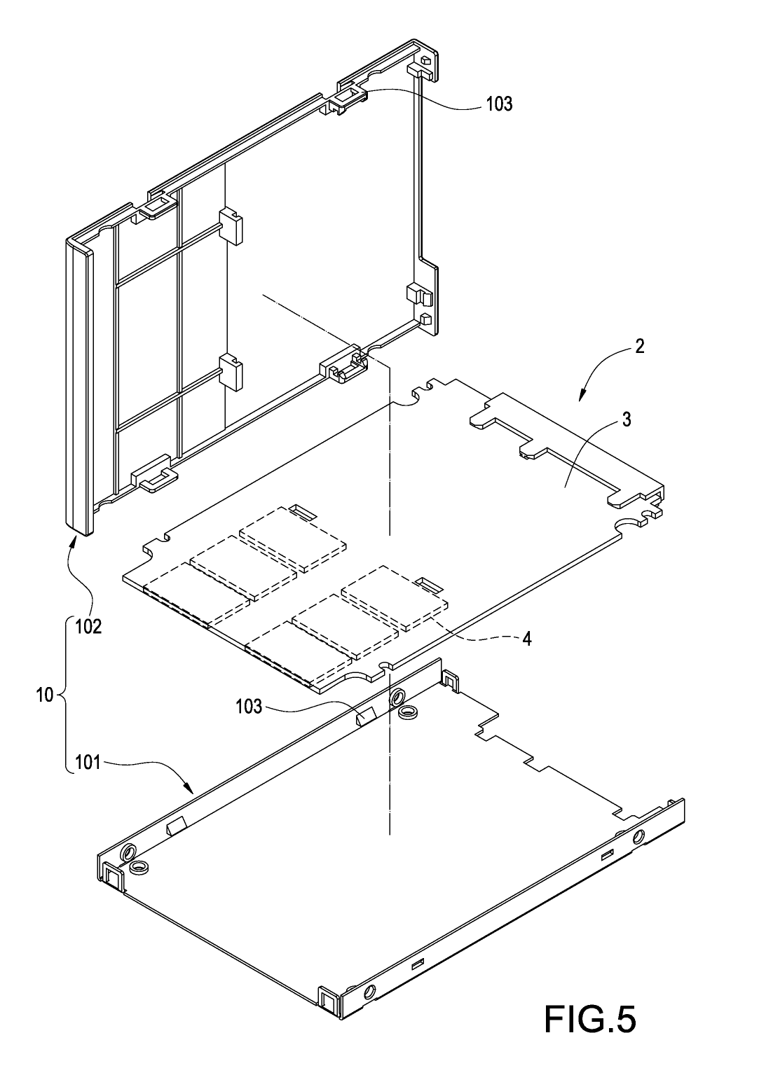

Please refer to FIGS. 3 and 4. When assembling the housing structure 1, the height adjustment plate 20 is fastened to the housing 10 by engaging the hooks 22 with the engagement recesses 11 for adjusting an overall height of the SSD 2.

Preferably, the engagement recess 11 is of an L-shape and the hook 22 is also of an L-shape. Additionally, the hook 22 is formed with an anti-slip block 221 and an engagement surface 220 for engaging with the engagement recesses 11. The anti-slip block 221 is on the engagement surface 220. In an embodiment of the invention, the height adjustment plate 20 includes a plurality of pairs of hook sets. A pair of hooks 22 of the hook sets is separately formed with the anti-slip blocks 221.

Please refer to FIG. 5. In an embodiment of the invention, the SSD 2 includes a circuit board 3 and a plurality of memory chips 4 on the circuit board 3. The housing 10 includes a first shell 101 and a second shell 102, which fasten to each other. The first shell 101 and second shell 102 have corresponding engagement portions 103 by which the shells 101, 102 can be fastened for accommodating the SSD 2.

The predetermined height of the height adjustment plate 20 can be varied according to actual requirements, for example, the height of 2.5 inch or 3.5 inch hard disk drive. Additionally, when a 1.8 inch form factor is required and the height of the housing 10 has satisfied this form factor, the height adjustment plate 20 may not be added to the housing 10. Thus, the invention can be applied to many form factors of solid-state drive.

It will be appreciated by persons skilled in the art that the above embodiment has been described by way of example only and not in any limitative sense, and that various alterations and modifications are possible without departure from the scope of the invention as defined by the appended claims.

What is claimed is:

1. A housing structure for a solid-state drive (SSD), comprising:
a housing, used for receiving the SSD, and having a plurality of engagement recesses on a surface thereof; and
a height adjustment plate, comprising a plate body having a predetermined height and a plurality of hooks formed on the plate body, wherein the hooks correspond to the engagement recesses in position, and the height adjustment plate is fastened to the housing by engaging the hooks with the engagement recesses for adjusting an overall height of the SSD.

2. The housing structure of claim 1, wherein the SSD includes a circuit board and a plurality of memory chips on the circuit board, the housing includes a first shell and a second shell, which fasten to each other, and the first shell and the second shell have corresponding engagement portions.

3. The housing structure of claim 1, wherein the engagement recesses are located on an outer edge of the housing.

4. The housing structure of claim 1, wherein each of the engagement recesses is of an L-shape and each of the hooks is of an L-shape.

5. The housing structure of claim 4, wherein the plate body is a frame plate, and the hooks are located on an edge of the plate body.

6. The housing structure of claim 5, wherein the plate body has at least one enclosure rib, the enclosure rib encloses an edge of the plate body, and the enclosure rib has a touch surface which is in contact with the housing.

7. The housing structure of claim 6, wherein the hooks protrude from the touch surface and extend parallelly toward the enclosure rib.

8. The housing structure of claim 4, wherein the hook is formed with an anti-slip block and an engagement surface for engaging with the engagement recesses, and the anti-slip block is on the engagement surface.

9. The housing structure of claim 8, wherein the height adjustment plate includes a plurality of pairs of hook sets, and a pair of hooks of the hook sets is separately formed with the anti-slip blocks.

10. The housing structure of claim 1, wherein the height adjustment plate corresponds to the housing in shape.
